(19) United States
(12) Patent Application Publication
(10) Pub. No.: US 2025/0120201 A1
(43) Pub. Date: Apr. 10, 2025

(54) PHOTOELECTRIC CONVERSION APPARATUS, MOVING BODY, AND EQUIPMENT

(71) Applicant: CANON KABUSHIKI KAISHA, Tokyo (JP)

(72) Inventors: AYMAN TAREK ABDELGHAFAR, Tokyo (JP); KAZUHIRO MORIMOTO, Kanagawa (JP)

(21) Appl. No.: 18/901,443

(22) Filed: Sep. 30, 2024

(30) Foreign Application Priority Data
Oct. 6, 2023 (JP) 2023-174631

(51) Int. Cl. H01L 27/146; G01S 7/481; G01S 7/51; G01S 17/894; G01S 17/931

(52) U.S. Cl. CPC H10F 39/8033; G01S 7/4816; G01S 7/51; G01S 17/894; G01S 17/931

(57) ABSTRACT

A photoelectric conversion apparatus in which a plurality of pixels are arranged on a substrate made of a first semiconductor material is provided. Each of the plurality of pixels includes: a first semiconductor portion provided on the substrate; a second semiconductor portion made of a second semiconductor material having a band gap smaller than a band gap of the first semiconductor material; a connection portion in contact with the first semiconductor portion and the second semiconductor portion and including at least one of the first semiconductor material and the second semiconductor material; and an electrode surrounding the connection portion. In orthogonal projection to a main surface of the substrate, the connection portion is smaller than the second semiconductor portion, and at least a part of the electrode is arranged between the first semiconductor portion and the second semiconductor portion.

### BACKGROUND

### Technical Field

The present disclosure relates to a photoelectric conversion apparatus, a moving body, and equipment.

### Description of the Related Art

Japanese Patent Laid-Open No. 2002-084235 discloses a device in which a Si-based avalanche layer and a Ge-based absorption layer are layered in order to improve sensitivity in an infrared region.

In a case where materials having lattice constants different from each other are layered, defects due to lattice mismatch may occur at a layer interface, and noise may increase.

### SUMMARY

According to some embodiments, a photoelectric conversion apparatus in which a plurality of pixels are arranged on a substrate made of a first semiconductor material, wherein each of the plurality of pixels comprises: a first semiconductor portion provided on the substrate; a second semiconductor portion made of a second semiconductor material having a band gap smaller than a band gap of the first semiconductor material; a connection portion in contact with the first semiconductor portion and the second semiconductor portion and including at least one of the first semiconductor material and the second semiconductor material; and an electrode surrounding the connection portion, wherein in orthogonal projection to a main surface of the substrate, the connection portion is smaller than the second semiconductor portion, and at least a part of the electrode is arranged between the first semiconductor portion and the second semiconductor portion is provided.

Some embodiments of the present disclosure provide techniques that are advantageous for noise suppression.

Further features of the present invention will become apparent from the following description of exemplary embodiments (with reference to the attached drawings).

### BRIEF DESCRIPTION OF THE DRAWINGS

FIG. 1 is a view illustrating a configuration example of a photoelectric conversion apparatus of the present embodiment.

FIG. 2 is a view illustrating a configuration example of a pixel array of the photoelectric conversion apparatus of FIG. 1.

FIG. 3 is a block diagram illustrating a configuration example of the photoelectric conversion apparatus of FIG. 1.

FIG. 4 is a circuit diagram illustrating a configuration example of a pixel of the photoelectric conversion apparatus of FIG. 1.

FIGS. 5A and 5B are views illustrating an operation example of the pixel of the photoelectric conversion apparatus of FIG. 1.

FIG. 6 is a cross-sectional view illustrating a configuration example of the pixel of the photoelectric conversion apparatus of FIG. 1.

FIG. 7 is an orthogonal projection view illustrating a configuration example of the pixel of FIG. 6.

FIG. 8 is an orthogonal projection view illustrating a configuration example of the pixel of FIG. 6.

FIG. 9 is a view explaining potential of the pixel of FIG. 6.

FIG. 10 is a cross-sectional view illustrating a configuration example of the pixel of the photoelectric conversion apparatus of FIG. 1.

FIG. 11 is a cross-sectional view illustrating a configuration example of the pixel of the photoelectric conversion apparatus of FIG. 1.

FIG. 12 is an orthogonal projection view illustrating a configuration example of the pixel of FIG. 11.

FIG. 13 is a cross-sectional view illustrating a configuration example of the pixel of the photoelectric conversion apparatus of FIG. 1.

FIG. 14 is a cross-sectional view illustrating a configuration example of the pixel of the photoelectric conversion apparatus of FIG. 1.

FIG. 15 is a cross-sectional view illustrating a configuration example of the pixel of the photoelectric conversion apparatus of FIG. 1.

FIG. 16 is an orthogonal projection view illustrating a configuration example of the pixel of FIG. 15.

FIG. 17 is a cross-sectional view illustrating a configuration example of the pixel of the photoelectric conversion apparatus of FIG. 1.

FIG. 18 is a circuit diagram illustrating a configuration example of the pixel of FIG. 17.

FIG. 19 is a functional block diagram of a photoelectric conversion system using the photoelectric conversion apparatus of the present embodiment.

FIGS. 20A and 20B are functional block diagrams of the photoelectric conversion system using the photoelectric conversion apparatus of the present embodiment.

FIG. 21 is a functional block diagram of the photoelectric conversion system using the photoelectric conversion apparatus of the present embodiment.

FIG. 22 is a functional block diagram of the photoelectric conversion system using the photoelectric conversion apparatus of the present embodiment.

FIGS. 23A and 23B are views illustrating a configuration example of the photoelectric conversion system using the photoelectric conversion apparatus of the present embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

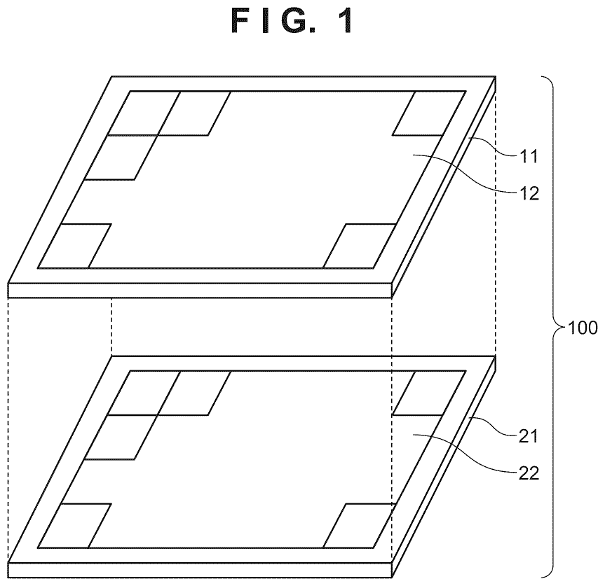

First, an avalanche photodiode (hereinafter, sometimes mentioned as APD) that can be used in a photoelectric conversion apparatus 100 described below will be described with reference to FIGS. 1 to 5. FIG. 1 is a view illustrating a configuration example of the photoelectric conversion apparatus 100. The photoelectric conversion apparatus 100 can be configured by two substrates of a sensor substrate 11 (hereinafter, sometimes mentioned as a substrate 11) and a circuit substrate 21 being layered and electrically connected. That is, the photoelectric conversion apparatus 100 may be a layered device. As described later, a semiconductor portion 301 in which a plurality of pixels 101 are arranged, structures 300 and 302, and the like are arranged on the substrate 11. The photoelectric conversion apparatus 100 can be a so-called back-side illumination photoelectric conversion apparatus in which light is incident from a surface 395 of the structure 300 of the substrate 11. A pixel region 12 including the plurality of pixels 101 is arranged on the substrate 11. In the circuit substrate 21, a circuit region 22 for processing a signal detected in the pixel region 12 is arranged.

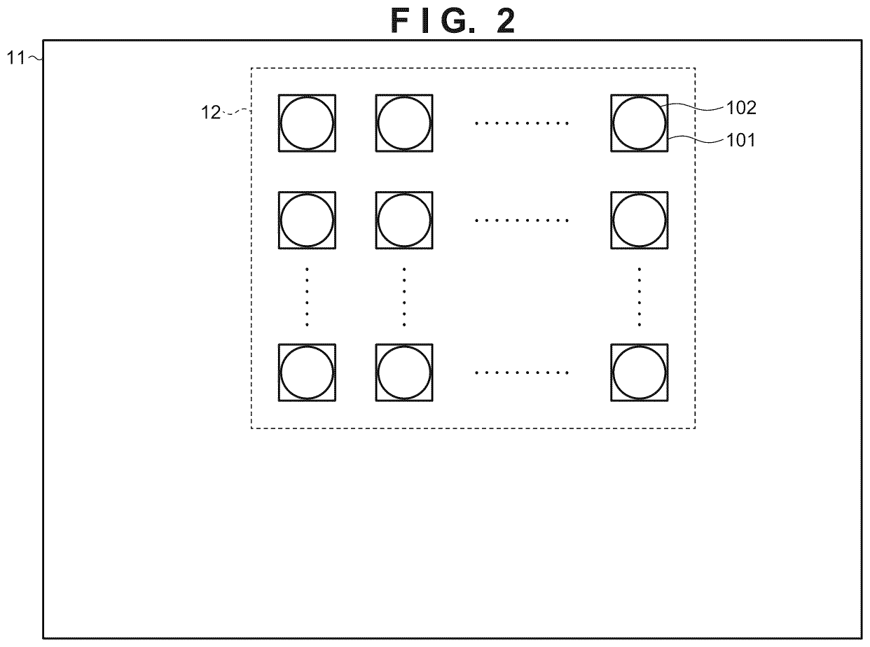

FIG. 2 is a view illustrating an arrangement example of the substrate 11. The pixels 101 each having a photoelectric conversion element 102 including the APD are arranged in a two-dimensional array in orthogonal projection to a main surface 393 of the substrate 11 and form the pixel region 12. The pixel 101 is typically a pixel for generating an image, but needs not necessarily generate an image when used in a distance measurement apparatus of a time of flight (ToF) method or the like. That is, the pixel 101 may be configured to measure the time when light reaches and a light amount.

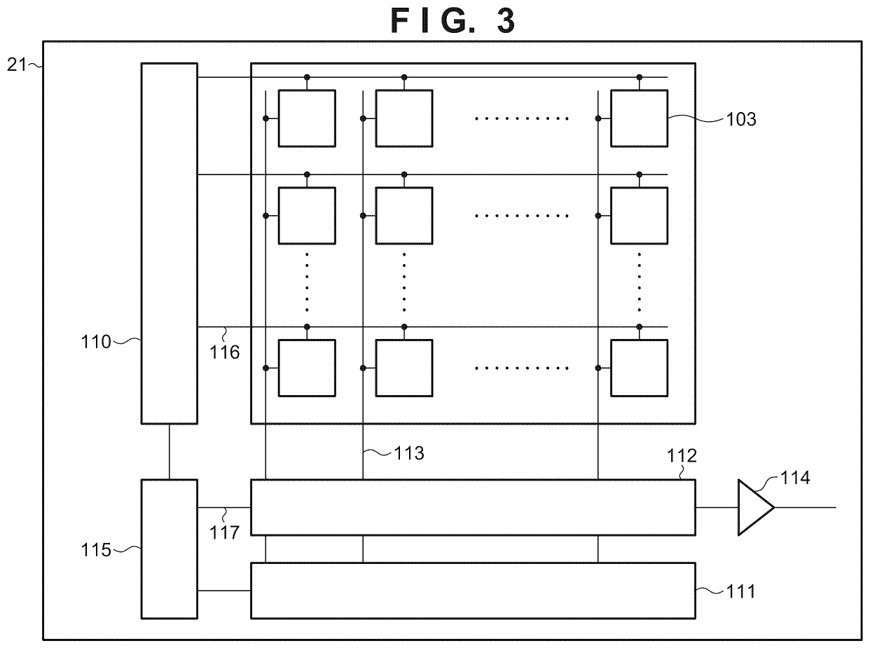

FIG. 3 is a view illustrating a configuration example of the circuit substrate 21. The circuit substrate 21 includes a signal processing circuit 103 that processes a charge photoelectrically converted by the photoelectric conversion element 102 illustrated in FIG. 2, a readout circuit 112, a control pulse generation circuit 115, a horizontal scan circuit 111, a signal line 113, and a vertical scan circuit 110. The signal processing circuit 103 illustrated in FIG. 3 may be arranged so as to correspond to each of the pixels 101 illustrated in FIG. 2. In that case, the pixel 101 (photoelectric conversion element 102) and the signal processing circuit 103 may be electrically connected via a connection wiring provided for each of the pixels 101.

The vertical scan circuit 110 receives a control pulse supplied from the control pulse generation circuit 115 and supplies the control pulse to each of the pixels 101. As the vertical scan circuit 110, a logic circuit such as a shift register or an address decoder can be used.

The signal output from the pixel 101 is processed by the signal processing circuit 103. The signal processing circuit 103 can be provided with a counter, a memory, and the like. A count value counted by the counter can be held as a digital value in the memory.

The horizontal scan circuit 111 inputs a control pulse for sequentially selecting each column to the signal processing circuit 103 in order to read a signal from the memory of the signal processing circuit 103 corresponding to each of the pixels 101 in which the digital signal is held. For the selected column, a signal is output to the signal line 113 from the signal processing circuit 103 corresponding to the pixel 101 selected by the vertical scan circuit 110. The signal output to the signal line 113 is output to a recording portion or a signal processing portion outside the photoelectric conversion apparatus 100 via an output circuit 114.

The arrangement of the pixels 101 in the pixel region 12 illustrated in FIG. 2 is not limited to a two-dimensional array. The pixels 101 may be arranged one-dimensionally. The function of the signal processing circuit 103 is not necessarily provided in all the pixels 101 (photoelectric conversion elements 102) one by one, and for example, one signal processing circuit 103 may be shared by the plurality of pixels 101 (photoelectric conversion elements 102) and signal processing may be sequentially performed.

As illustrated in FIGS. 2 and 3, a plurality of the signal processing circuits 103 can be arranged in a region overlapping the pixel region 12 in orthogonal projection to the pixel region 12. The vertical scan circuit 110, the horizontal scan circuit 111, the readout circuit 112, the output circuit 114, the control pulse generation circuit 115, and the like can be arranged to overlap between an end of the substrate 11 and an end of the pixel region 12. In other words, the substrate 11 has the pixel region 12 and a non-pixel region arranged around the pixel region 12. In that case, the vertical scan circuit 110, the horizontal scan circuit 111, the readout circuit 112, the output circuit 114, and the control pulse generation circuit 115 can be arranged in a region overlapping the non-pixel region.

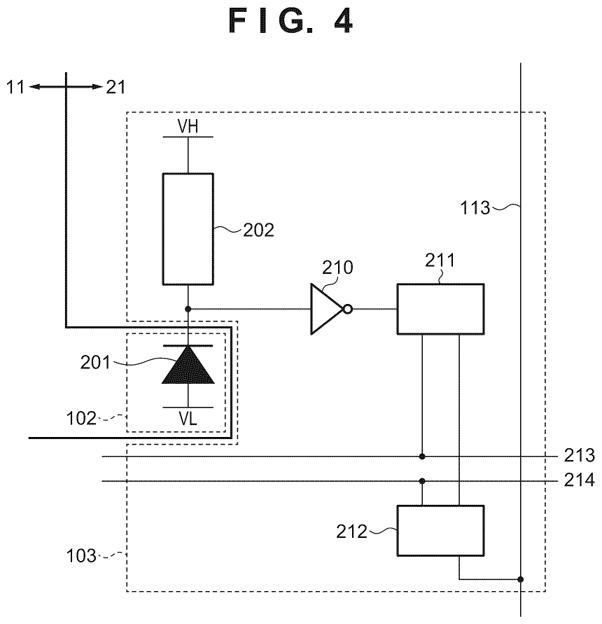

FIG. 4 is an example of a block diagram including an equivalent circuit focusing on one pixel 101 (photoelectric conversion element 102). In FIG. 4, the photoelectric conversion element 102 including an APD 201 is provided on the substrate 11, and the other configurations are provided on the circuit substrate 21.

The APD 201 generates a charge pair corresponding to incident light by photoelectric conversion. An anode of the APD 201 is supplied with a potential VL. A cathode of the APD 201 is supplied with a potential VH higher than the potential VL supplied to the anode. The anode and the cathode are supplied with a reverse bias voltage so that the APD 201 performs an avalanche multiplication operation. By bringing into a state of supplying such a reverse bias voltage, the charge generated by the incident light causes avalanche multiplication, and an avalanche current is generated.

In a case where a reverse bias voltage is supplied to the APD 201, there are a Geiger mode in which operation is performed with a potential difference (voltage) between the anode and the cathode being larger than a breakdown voltage, and a linear mode in which operation is performed with a potential difference between the anode and the cathode being in the vicinity of the breakdown voltage or equal to or less than the breakdown voltage. An APD operated in the Geiger mode is called a single photon avalanche diode (SPAD). For example, the potential VL is −30 V, and the potential VH is 1 V. The APD 201 may be operated in the linear mode or may be operated in the Geiger mode.

A quench element 202 is connected between a power source that supplies the potential VH and the APD 201. The quench element 202 functions as a load circuit (quench circuit) at the time of signal multiplication by avalanche multiplication, and suppresses avalanche multiplication by suppressing the voltage supplied to the APD 201 (quench operation). By passing a current corresponding to a voltage drop in the quench operation, the quench element 202 returns the voltage supplied to the APD 201 to the voltage (VH-VL) (recharge operation).

The signal processing circuit 103 can include a waveform shaping circuit 210, a counter circuit 211, and a selection circuit 212. In the present description, the signal processing circuit 103 may include any of the waveform shaping circuit 210, the counter circuit 211, and the selection circuit 212.

The waveform shaping circuit 210 shapes a potential change of the cathode of the APD 201 obtained at the time of photon detection, and outputs a pulse signal. For example, an inverter circuit is used as the waveform shaping circuit 210. In the configuration illustrated in FIG. 4, an example in which one inverter is used as the waveform shaping circuit 210 is illustrated. However, the present invention is not limited to this, and a circuit in which a plurality of inverters are connected in series may be used as the waveform shaping circuit 210, or another circuit having a waveform shaping effect may be used.

The counter circuit 211 counts the pulse signal output from the waveform shaping circuit 210 and holds a count value. When a control pulse pRES is supplied from the vertical scan circuit 110 via a drive line 213, the signal held in the counter circuit 211 is reset.

The selection circuit 212 is supplied with a control pulse pSEL from the vertical scan circuit 110 illustrated in FIG. 3 via a drive line 214 illustrated in FIG. 4, and electrical connection/disconnection between the counter circuit 211 and the signal line 113 is switched. The selection circuit 212 includes a buffer circuit for outputting a signal, for example.

A switch element such as a transistor may be arranged between the quench element 202 and the APD 201 or between the photoelectric conversion element 102 and the signal processing circuit 103, so that electrical connection can be switched. Similarly, supply of the potential VH or the potential VL to be supplied to the photoelectric conversion element 102 may be electrically switchable using a switch element such as a transistor.

In the present embodiment, a configuration in which the counter circuit 211 is arranged in the signal processing circuit 103 has been described. However, the present invention is not limited to this, and the photoelectric conversion apparatus 100 may be configured to acquire pulse detection timing by using a time-to-digital conversion circuit (TDC) and the memory in place of the counter circuit 211. In that case, generation timing of the pulse signal output from the waveform shaping circuit 210 is converted into a digital signal by the TDC. The TDC is supplied with a control pulse pREF (reference signal) from the vertical scan circuit 110 via a drive line for measurement of the timing of the pulse signal. With reference to the control pulse pREF, the TDC acquires, as a digital signal, a signal when input timing of the signal output from each of the pixels 101 via the waveform shaping circuit 210 is a relative time.

In the configuration illustrated in FIG. 4, an example in which the quench element 202, the waveform shaping circuit 210, the counter circuit 211, and the selection circuit 212 are arranged on one circuit substrate 21 has been described, but the present invention is not limited to this. For example, the quench element 202 and the waveform shaping circuit 210 may be arranged on one substrate, the counter circuit 211 and the selection circuit 212 may be arranged on another substrate, and these substrates may be layered.

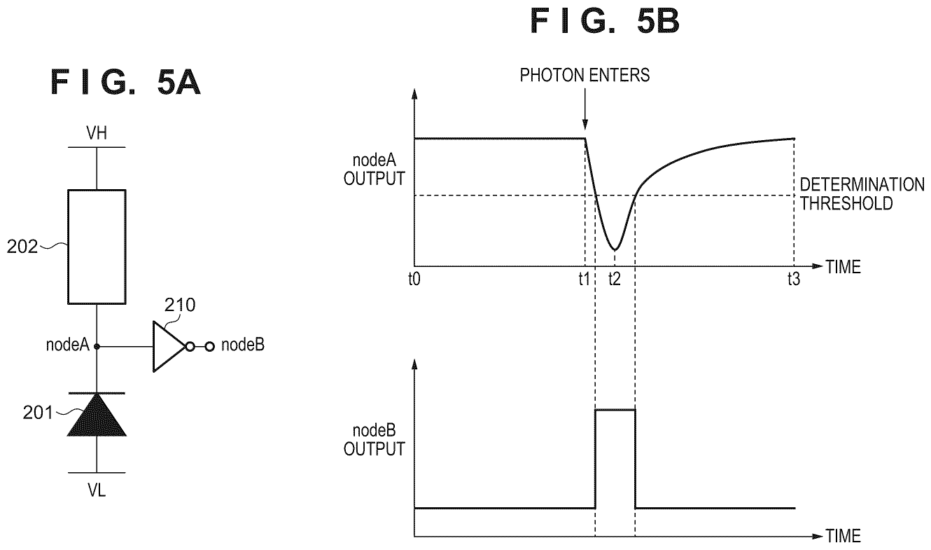

FIGS. 5A and 5B are views schematically illustrating a relationship between an operation of the APD 201 and an output signal. FIG. 5A is a view in which the APD 201, the quench element 202, and the waveform shaping circuit 210 illustrated in FIG. 4 are extracted. Here, let an input side of the waveform shaping circuit 210 be node A, and an output side thereof be node B. FIG. 5B illustrates waveform changes of node A and node B.

From time t0 to time t1, the APD 201 is applied with a potential difference (voltage) between the potential VH and the potential VL. When a photon enters the APD 201 at time t1, avalanche multiplication occurs in the APD 201, an avalanche multiplication current flows through the quench element 202, and the potential of node A drops. When the voltage drop further increases and the potential difference applied to the APD 201 decreases, the avalanche multiplication of the APD 201 stops as shown at time t2, and the potential level of node A does not drop by a certain value or more. Thereafter, between time t2 and time t3, a current for compensating for the voltage drop from the potential VL flows in node A, and node A settles to the original potential level at time t3. At this time, a part where the output waveform exceeds a certain threshold in node A is waveform-shaped by the waveform shaping circuit 210 and is output as a signal to node B.

The arrangement of the signal line 113, the readout circuit 112, and the output circuit 114 is not limited to the configuration illustrated in FIG. 3. For example, the signal line 113 may be arranged to extend in a row direction (lateral direction in FIG. 3), and the readout circuit 112 may be arranged in a destination where the signal line 113 extends.

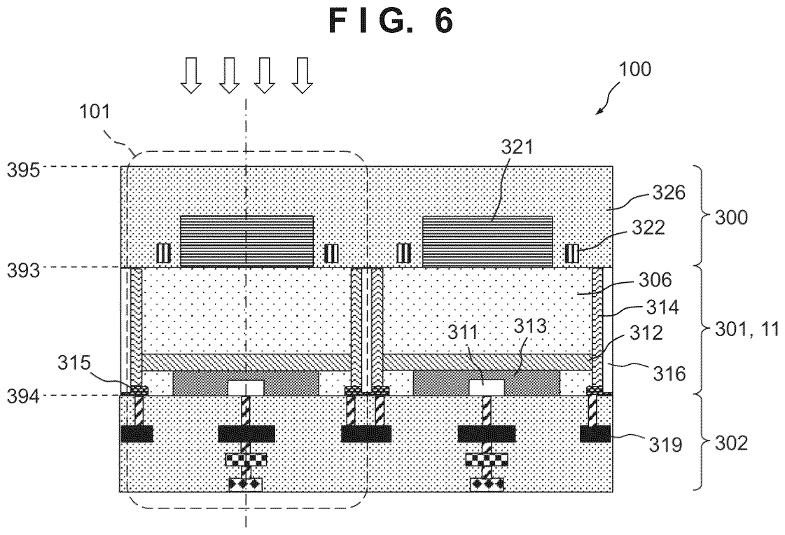

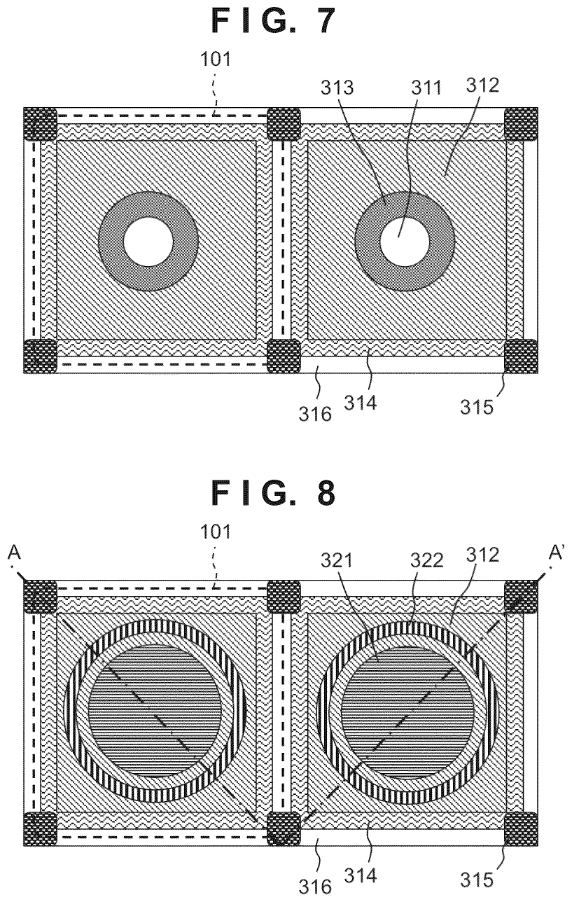

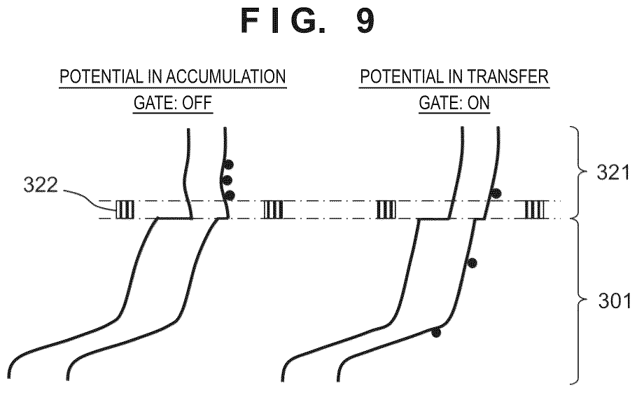

Next, the configuration of the pixel 101 arranged in the photoelectric conversion apparatus 100 will be described in detail. FIG. 6 is a cross-sectional view illustrating the configuration of the pixel 101 arranged in the pixel region 12. FIG. 7 is an orthogonal projection view of the vicinity of a main surface 394 of the substrate 11 illustrated in FIG. 6. FIG. 8 is an orthogonal projection view of the substrate 11 and the structure 300 in the vicinity of the main surface 393 of the substrate 11 illustrated in FIG. 6. FIG. 6 is a cross-sectional view taken along line A-A′ illustrated in FIG. 8.

In the photoelectric conversion apparatus 100, the plurality of pixels 101 are arranged on the substrate 11 made of a semiconductor material. Each of the plurality of pixels 101 includes the semiconductor portion 301 provided on the substrate 11 and a semiconductor portion 321 in contact with the semiconductor portion 301 and made of a semiconductor material having a band gap smaller than that of the semiconductor material of the substrate 11.

In the semiconductor portion 301, each of the pixels 101 includes a semiconductor region 311 of a first conductivity type, a semiconductor region 312 of a second conductivity type, a semiconductor region 313 of the first conductivity type, a semiconductor region 314 of the second conductivity type, a semiconductor region 315 of the second conductivity type, and a semiconductor region 306. Each of the pixels 101 is separated by a trench structure 316. Examples of the semiconductor material used for the substrate 11 include silicon. Therefore, each of the semiconductor regions 306 and 311 to 315 of the semiconductor portion 301 is a region in which an impurity corresponding to the conductivity type is injected into silicon.

In the above-described APD 201, the semiconductor region 311 of the first conductivity type and the semiconductor region 312 of the second conductivity type are arranged, and the semiconductor region 311 and the semiconductor region 312 form a PN junction. It can also be said that the APD 201 includes an avalanche multiplication region where the semiconductor region 311 of the first conductivity type and the semiconductor region 312 of the second conductivity type arranged between the semiconductor region 311 and the semiconductor portion 321 are in contact with each other. By applying a predetermined reverse bias voltage between the semiconductor region 311 and the semiconductor region 312, avalanche multiplication occurs when light is incident. In a region between the semiconductor region 312 and the main surface 393 of the semiconductor portion 301, the semiconductor region 306 having a low impurity concentration (e.g., an intrinsic layer, a P-type epitaxial layer, or an N-type epitaxial layer) is arranged so as to come into contact with the semiconductor region 312. By applying a reverse bias between the semiconductor regions 311 and 313 and the semiconductor region 312, a depletion layer expands toward the side of the main surface 393 of the semiconductor portion 301. Here, the semiconductor region 313 functions as a field relief region that relieves the electric field at an end of the semiconductor region 311.

The APD 201 is electrically connected to the wiring pattern arranged on the structure 302 on the main surface 394 of the semiconductor portion 301. The structure 302 is a region in which one or more layers of wiring patterns and the like are arranged on an insulator. The semiconductor region 311 can function as a cathode electrode of the APD 201. The semiconductor region 315 is a semiconductor region of the first conductivity type with high concentration, and can function as the anode of the APD 201.

In the structure 300, the semiconductor portion 321 using a semiconductor material having a band gap smaller than that of the substrate 11 (semiconductor portion 301) is arranged. The structure 300 is a region in which the semiconductor portion 321 and an electrode 322 described later are arranged on an insulator 326.

Since the semiconductor portion 321 has a band gap smaller than that of the substrate 11 (semiconductor portion 301), the quantum efficiency in the near-infrared wavelength band is high. The semiconductor can photoelectrically convert light having energy exceeding the band gap. Since the band gap of the semiconductor portion 321 is smaller than the band gap of the semiconductor portion 301, energy required for photoelectric conversion is also small. Therefore, the semiconductor portion 321 can also photoelectrically convert light having a longer wavelength than light that can be photoelectrically converted by silicon used for the semiconductor portion 301. Examples of the semiconductor material used for the semiconductor portion 321 include germanium. The germanium used for the semiconductor portion 321 may be used as an intrinsic semiconductor. The germanium used for the semiconductor portion 321 may be an impurity semiconductor doped with impurities such as phosphorus, arsenic, antimony, boron, aluminum, and gallium. The semiconductor material used for the semiconductor portion 321 is not limited to germanium, and may be, for example, indium gallium arsenide, germanium tin, or the like.

Since the lattice constant of each atom is different between the semiconductor material constituting the semiconductor portion 301 and the semiconductor material constituting the semiconductor portion 321, a defect due to lattice mismatch may occur at the layer interface where the semiconductor portion 301 and the semiconductor portion 321 are layered. For example, a defect of the layer interface becomes a generation source of a leakage current, and thus there is a possibility that noise increases with respect to a signal generated in the pixel 101.

Therefore, in the present embodiment, the electrode 322 arranged so as to surround a part of the side surface of the semiconductor portion 321 is arranged in the structure 300. As illustrated on the left side of FIG. 9, the potential applied to the electrode 322 is controlled such that a barrier is formed for the charges accumulated in the semiconductor portion 321 during a predetermined accumulation time. Due to this, the charges accumulated in the semiconductor portion 321 do not flow to the semiconductor portion 301. Next, when the accumulation time ends, as illustrated on the right side of FIG. 9, the potential applied to the electrode 322 is controlled such that no barrier is formed with respect to the charges accumulated in the semiconductor portion 321. Due to this, the charges accumulated in the semiconductor portion 321 move to the semiconductor portion 301. Due to the charges moved to the semiconductor portion 301, the APD 201 arranged in the semiconductor portion 301 causes avalanche multiplication, and an avalanche current is generated.

In a case where the electrode 322 is not arranged, the APD 201 arranged in the semiconductor portion 301 may cause avalanche multiplication due to a leakage current caused by a defect at a layer interface between the semiconductor portion 301 and the semiconductor portion 321. However, by arranging the electrode 322, charges can be accumulated in the semiconductor portion 321, and the accumulated charges can be transferred to the semiconductor portion 301. This can improve the S/N ratio and suppress noise in the pixel 101.

The electrode 322 is an electrode that controls a gate between the semiconductor portion 301 and the semiconductor portion 321 as described above. Therefore, in a direction intersecting the main surface 393 of the substrate 11, the electrode 322 can be arranged in a region close to the semiconductor portion 321 with respect to the semiconductor portion 301. For example, the center position of the electrode 322 in the direction intersecting the main surface 393 of the substrate 11 may be closer to the semiconductor portion 301 than the center position of the semiconductor portion 321 in the direction intersecting the main surface 393 of the substrate 11.

Although not illustrated in FIG. 6, a joint portion for extracting hole charges may be arranged between the semiconductor portion 321 and the semiconductor region 314 of the second conductivity type. The potential VL supplied to the anode of the APD 201 is supplied to the semiconductor portion 321 via the semiconductor region 314, and a charge is induced.

Since the electrode 322 is an electrode that controls the gate between the semiconductor portion 301 and the semiconductor portion 321, it is not in contact with the semiconductor portion 301 and the semiconductor portion 321. In order to form the potential gradient illustrated in FIG. 9 in the semiconductor portion 321, it is more suitable for the electrode 322 to have a larger area facing the side surface of the semiconductor portion 321. On the other hand, in order to suppress the parasitic capacitance between the electrode 322 and the semiconductor portion 301, it is more suitable for the electrode 322 to have a smaller area facing the semiconductor portion 301. For example, in the electrode 322, the area of the inner side surface extending in a direction intersecting the surface facing the semiconductor portion 301 may be larger than the area of the surface facing the semiconductor portion 301.

In order to make the distribution of the potential gradient in the direction intersecting the main surface 393 of the substrate 11 formed in the semiconductor portion 321 more uniform, as illustrated in FIG. 8, the semiconductor portion 321 may be circular in orthogonal projection with respect to the main surface 393 of the substrate 11. That is, the semiconductor portion 321 may have a columnar shape. The electrode 322 may have a donut shape surrounding the semiconductor portion 321.

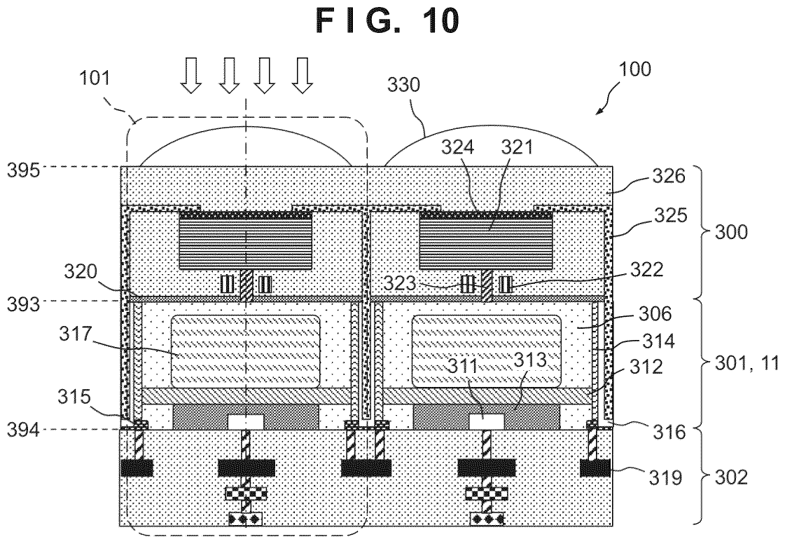

FIG. 10 is a view illustrating a modification of the pixel 101 described above. In the pixel 101 illustrated in FIG. 6, the semiconductor portion 301 and the semiconductor portion 321 are in contact with each other. On the other hand, in the pixel 101 illustrated in FIG. 10, a connection portion 323 in contact with the semiconductor portion 301 and the semiconductor portion 321 is arranged. The electrode 322 is arranged so as to surround this connection portion 323. At least a part of the electrode 322 is arranged between the semiconductor portion 301 and the semiconductor portion 321.

As described above, since the lattice constant of each atom is different between the semiconductor material constituting the semiconductor portion 301 and the semiconductor material constituting the semiconductor portion 321, a defect due to lattice mismatch may occur at the layer interface. Therefore, the connection portion 323 having an area smaller than that of the semiconductor portion 301 in orthogonal projection to the main surface of the substrate is arranged between the semiconductor portion 321 and the semiconductor portion 321. Due to this, as compared with the case where the semiconductor portion 301 and the semiconductor portion 321 are directly joined, the joint area of the members made of different semiconductor materials is reduced, and the influence of lattice mismatch at the layer interface is suppressed.

The connection portion 323 includes at least one of the semiconductor material of the substrate 11 (semiconductor portion 301) and the semiconductor material of the semiconductor portion 321. An effect of suppressing the influence of lattice mismatch can be obtained regardless of whether the semiconductor material constituting the connection portion 323 is the semiconductor material of the semiconductor portion 301 or the semiconductor material of the semiconductor portion 321. Since a transition defect generated from the layer interface with the substrate 11 (e.g., silicon) can be terminated in the region when the connection portion 323 is formed, the semiconductor material (e.g., germanium) of the semiconductor portion 321 may be used for the connection portion 323. On the other hand, even in a case where the connection portion 323 is made of only the semiconductor material of the semiconductor portion 301, the effect of suppressing generation of noise can be obtained by making the layer area of the interface smaller than the area of the semiconductor portion 321. For example, the connection portion 323 may be a mixture (mixed crystal) of the semiconductor materials of the semiconductor portion 301 and the semiconductor portion 321. Furthermore, for example, the connection portion 323 may change from a region where the concentration of the semiconductor material used for the semiconductor portion 301 is high (e.g., more than 50% and 100% or less) to region where the concentration of the semiconductor material used for the semiconductor portion 321 is high (e.g., more than 50% and 100% or less), from the surface in contact with the semiconductor portion 301 toward the surface in contact with the semiconductor portion 321.

As illustrated in FIG. 10, the electrode 322 may surround the connection portion 323 and needs not surround the semiconductor portion 321. In orthogonal projection to the main surface 393 of the substrate 11, since the connection portion 323 is smaller than the semiconductor portion 321, controllability of controlling the above-described potential by the electrode 322 is improved.

Since the electrode 322 is an electrode that controls the gate between the semiconductor portion 301 and the semiconductor portion 321, it is not in contact with the semiconductor portion 301 and the semiconductor portion 321. Similarly, the electrode 322 is not in contact with the connection portion 323. In order to form the potential gradient illustrated in FIG. 9 in the semiconductor portion 321, it is more suitable for the electrode 322 to have a larger area facing the side surface of the connection portion 323. On the other hand, in order to suppress the parasitic capacitance between the electrode 322 and the semiconductor portion 301, it is more suitable for the electrode 322 to have a smaller area facing the semiconductor portion 301. For example, in the electrode 322, the area of the inner side surface extending in a direction intersecting the surface facing the semiconductor portion 301 may be larger than the area of the surface facing the semiconductor portion 301.

In order to make the distribution of the potential gradient in the direction intersecting the main surface 393 of the substrate 11 formed in the connection portion 323 more uniform, the connection portion 323 may be circular in orthogonal projection with respect to the main surface 393 of the substrate 11. That is, the connection portion 323 may have a columnar shape. The electrode 322 may have a donut shape surrounding the connection portion 323.

The pixel 101 illustrated in FIG. 10 further includes a charge collection region 317, a pinning layer 320, a semiconductor region 324, and a light shielding portion 325.

The charge collection region 317 is a semiconductor region of the first conductivity type in contact with the semiconductor region 312 arranged between the avalanche multiplication region described above and the semiconductor portion 321. The charge collection region 317 is a region having an impurity concentration lower than that of the semiconductor region 311. The semiconductor region 306 arranged between the charge collection region 317 and the semiconductor portion 321 can be a region having an impurity concentration lower than that of the charge collection region 317. By arranging the charge collection region 317, a potential gradient from a surface (the main surface 393 of the substrate 11) into which charges are injected from the semiconductor portion 321 of the semiconductor portion 301 via the connection portion 323 to the avalanche multiplication region can be formed, and transfer of charges can be promoted.

The pinning layer 320 is arranged to cover the surface of the semiconductor portion 301 (the main surface 393 of the substrate 11). It can also be said that the pinning layer 320 is arranged to seal the surface of the semiconductor portion 301. By arranging the pinning layer 320 to be in contact with the surface of the semiconductor portion 301, a hole is induced in the vicinity of the surface of the semiconductor portion 301, and a dark current is suppressed. For the pinning layer 320, an insulating film made of hafnium oxide, zirconium oxide, aluminum oxide, titanium oxide, tantalum oxide, or the like can be used. An opening for exposing the semiconductor portion 301 is arranged in a part of the pinning layer 320, and the connection portion 323 is arranged in a part where the surface of the semiconductor portion 301 is exposed.

The light shielding portion 325 is arranged between the respective pixels 101. The light shielding portion 325 may be embedded in the trench structure 316. By arranging the light shielding portion 325, crosstalk between the pixels 101 is suppressed. For example, a metal material is used for the light shielding portion 325.

As illustrated in FIG. 10, the light shielding portion 325 may supply a potential to the semiconductor portion 321 via the semiconductor region 324. The semiconductor region 324 is a region arranged to suppress contact resistance between the semiconductor portion 321 and the light shielding portion 325, and is a region having an impurity concentration higher than that of the semiconductor portion 321. For example, the semiconductor portion 321 is supplied with the potential VL supplied to the anode of the APD 201. However, the present invention is not limited to this, and a potential different from the potential VL may be supplied. Therefore, as illustrated in FIG. 10, the light shielding portion 325 is not in contact with the semiconductor region 315 in the trench structure 316. On the other hand, in a case where the potential VL supplied to the anode of the APD 201 is supplied to the semiconductor portion 321, the light shielding portion 325 may be in contact with the semiconductor region 315.

The light shielding portion 325 supplies a potential to the semiconductor portion 321 from the side of the surface of the semiconductor portion 321 on the opposite side to the surface facing the semiconductor portion 301. Since the light shielding portion 325 is arranged on the side of the surface 395 of the structure 300 where light enters with respect to the semiconductor portion 321, the influence of crosstalk between the pixels 101 can be further suppressed.

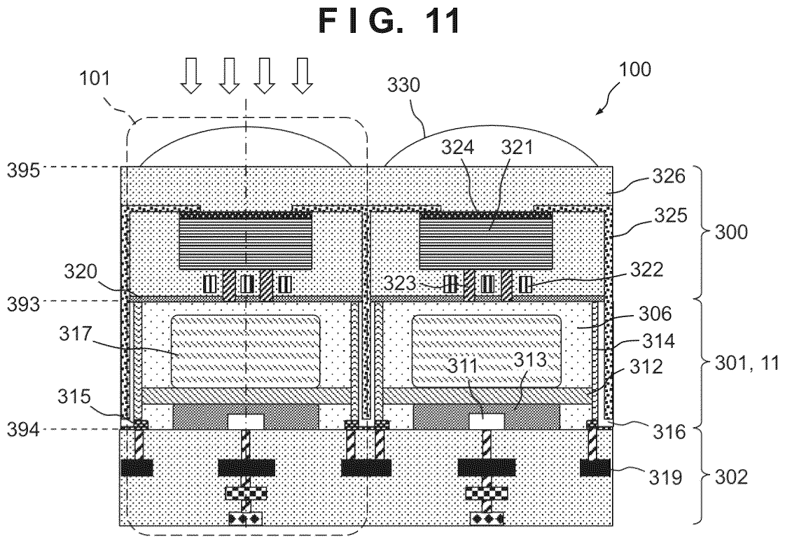

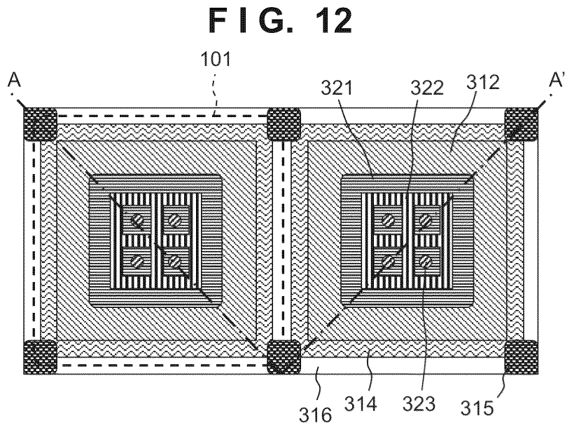

FIG. 11 is a view illustrating a modification of the pixel 101 illustrated in FIG. 10. FIG. 12 is an orthogonal projection view of the substrate 11 and the structure 300 in the vicinity of the main surface 393 of the substrate 11 illustrated in FIG. 11. In the configuration illustrated in FIG. 10, one connection portion 323 is arranged in one pixel 101. On the other hand, in the configuration illustrated in FIG. 11, a plurality of the connection portions 323 are arranged in one pixel. In this case, the electrode 322 is arranged so as to surround each of the plurality of connection portions 323. In the configuration illustrated in FIG. 12, the electrode 322 surrounds the respective connection portions 323 in a rectangular shape, but the present invention is not limited to this, and the electrode 322 may surround the connection portion 323 in a circular shape.

Since the connection portion 323 is smaller than the semiconductor portion 321 in orthogonal projection to the main surface 393 of the substrate 11, controllability of controlling the above-described potential by the electrode 322 is improved also in the configuration illustrated in FIG. 11. Since the plurality of connection portions 323 are arranged, charges from the semiconductor portion 321 to the semiconductor portion 301 more easily move than in the configuration illustrated in FIG. 10.

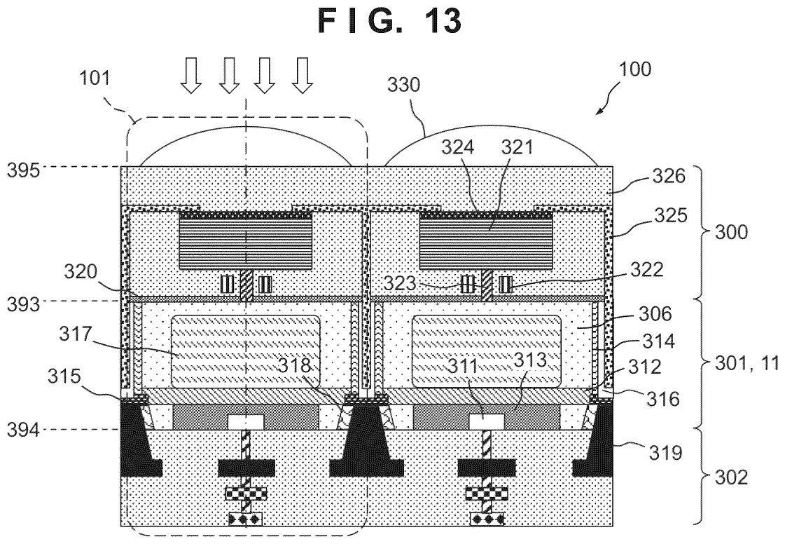

FIG. 13 is a view illustrating a modification of the pixel 101 illustrated in FIG. 10. In the configuration illustrated in FIG. 10, a path for supplying the potential VL of the anode of the APD 201 from a potential supply electrode 319 to the semiconductor region 312 passes through the semiconductor region 315 and the semiconductor region 314. The semiconductor region 306 is arranged between the semiconductor regions 314 and 315 and the semiconductor regions 311 and 313 supplied with the potential VH of the cathode of the APD 201. The semiconductor region 306 is a region having a low impurity concentration, but when applied with a potential difference (voltage) between the potential VH and the potential VL, a leakage current may flow. The leakage current can cause noise.

Therefore, as illustrated in FIG. 13, the pixel 101 may have a configuration in which the semiconductor region 315 is not in contact with the semiconductor region 306 not via the semiconductor region 312 between the semiconductor region 315 and the semiconductor regions 311 and 313. In the configuration illustrated in FIG. 13, the potential supply electrode 319 for supplying a potential to the semiconductor region 312 via the semiconductor region 315 of the second conductivity type is arranged. This potential supply electrode 319 includes a side surface and an upper surface in contact with the semiconductor region 315. In this case, the side surface of the potential supply electrode 319 is covered with an insulator 318, and the upper surface of the potential supply electrode 319 is arranged at a position closer to the semiconductor portion 321 than the semiconductor region 313. For example, as illustrated in FIG. 13, the semiconductor region 315 may be arranged in contact with the semiconductor region 312. For example, the semiconductor region 315 may be in contact with a region of the second conductivity type in contact with the semiconductor region 312.

The configuration illustrated in FIG. 13 can suppress a leakage current via the semiconductor region 306 between the semiconductor regions 314 and 315 and the semiconductor regions 311 and 313. This can suppress noise generated in the pixel 101.

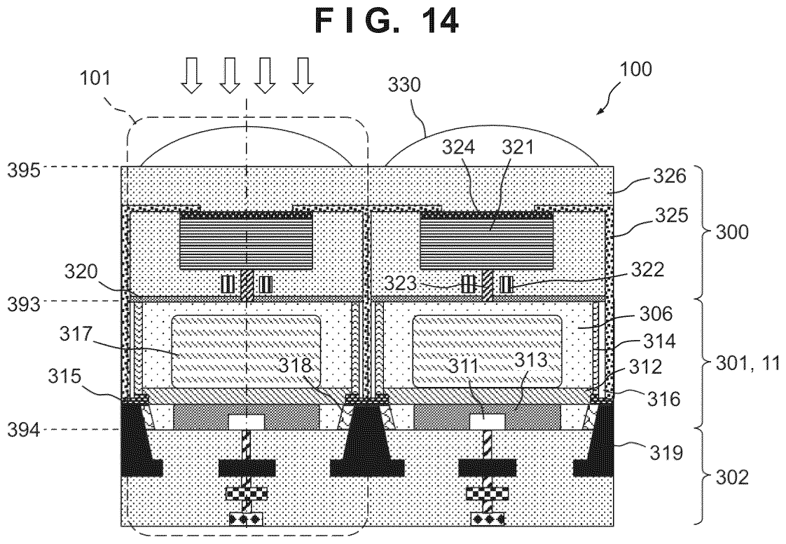

As illustrated in FIG. 14, the potential supply electrode 319 may be electrically connected to the light shielding portion 325 via the semiconductor region 315. In the case of the configuration illustrated in FIG. 14, the semiconductor portion 321 is supplied with the potential VL supplied to the anode of the APD 201 via the light shielding portion 325. However, the present invention is not limited to this, and as illustrated in FIG. 13, the light shielding portion 325 needs not be in contact with the semiconductor region 315, and in that case, the semiconductor portion 321 may be supplied with a potential different from the potential VL. Also in the configuration illustrated in FIG. 13, the semiconductor portion 321 may be supplied with the potential VL supplied to the anode of the APD 201 via the light shielding portion 325.

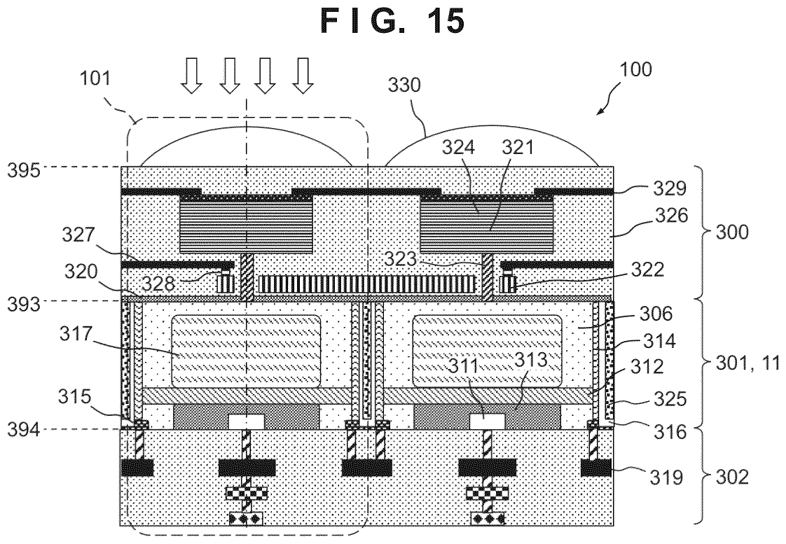

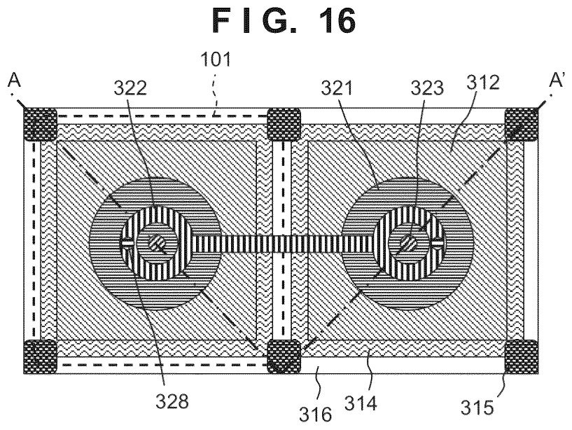

FIG. 15 is a view illustrating a modification of the pixel 101 illustrated in FIG. 10. FIG. 16 is an orthogonal projection view of the substrate 11 and the structure 300 in the vicinity of the main surface 393 of the substrate 11 illustrated in FIG. 15. The configuration illustrated in FIG. 10 describes that the potential is supplied to the semiconductor portion 321 via the light shielding portion 325. However, the present invention is not limited to this.

The semiconductor portion 321 and the electrode 322 are arranged in the insulator 326 arranged on the substrate 11. The insulator 326 is provided with wiring patterns 327 and 329 for supplying potentials to the semiconductor portion 321 and the electrode 322, respectively. The wiring patterns 327 and 328 may be supplied with power outside the pixel region 12 in which the plurality of pixels 101 are arranged. The wiring patterns 327 and 329 for supplying a potential to the semiconductor portion 321 and the electrode 322 are arranged in the structure 300. As compared with the case where a pattern corresponding to the wiring patterns 327 and 329 is arranged in the structure 302, the parasitic capacitance added to the semiconductor region 311 can be reduced, and as a result, the power consumption can be suppressed. Only one of the wiring pattern 327 and the wiring pattern 329 may be arranged in the structure 300, and a pattern corresponding to the other may be arranged in the structure 302.

For example, a potential different from the potential VL supplied from the potential supply electrode 319 to the semiconductor region 312 via the semiconductor region 315 may be supplied to the semiconductor portion 321 via the wiring pattern 329. When charges are transferred from the semiconductor portion 321 to the semiconductor portion 301, a potential that can form a potential gradient from the semiconductor portion 321 toward the semiconductor portion 301 can be supplied to the semiconductor portion 321 via the wiring pattern 329.

As illustrated in FIGS. 15 and 16, the electrodes 322 of the pixels 101 arranged adjacent to each other may be integrally formed. For example, it is conceivable to transfer a charge from the semiconductor portion 321 to the semiconductor portion 301 for each of the pixels 101 arranged for each row among the plurality of pixels 101. In this case, the electrodes 322 of the pixels 101 arranged in one row may be integrally formed. This enables the density of the wiring pattern 327 to be reduced, and the design of the photoelectric conversion apparatus 100 to be facilitated. By integrally forming the electrode 322, for example, the number of conductive vias 328 connecting the wiring pattern 327 and the electrode 322 is reduced, and process management when manufacturing the photoelectric conversion apparatus 100 can be facilitated.

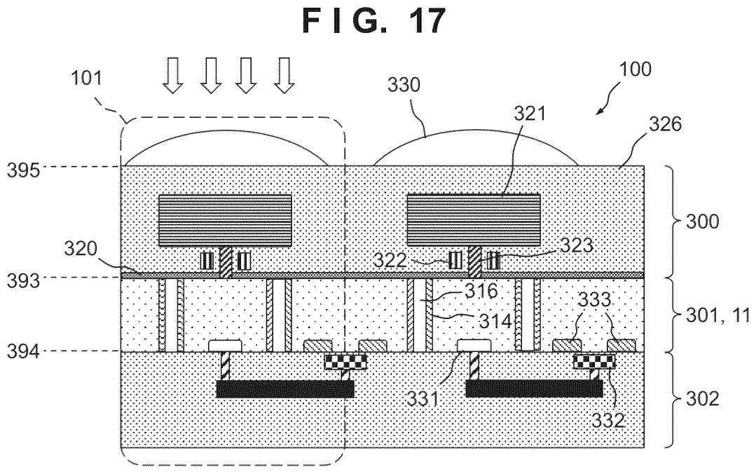

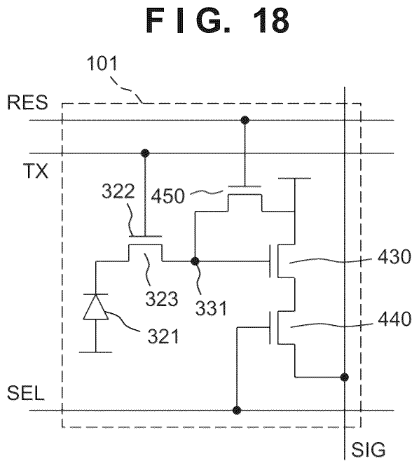

In each of the above-described embodiments, an example has been described in which the APD 201 is arranged in the semiconductor portion 301, and a signal corresponding to a charge generated in the semiconductor portion 321 is amplified and read out. However, the present disclosure is not limited to arranging the APD 201 in the semiconductor portion 301. FIG. 17 is a view illustrating a modification of the pixel 101 illustrated in FIG. 10. FIG. 18 is a circuit diagram illustrating a configuration example of the pixel 101.

As illustrated in FIG. 17, a semiconductor region 331 functioning as floating diffusion is arranged in the semiconductor portion 301. The semiconductor region 331 is connected to a gate 332 of a transistor including the gate 332 and a semiconductor region 333 functioning as source-drain.

As illustrated in FIG. 18, the pixel 101 can include the semiconductor portion 321 functioning as a photoelectric conversion element, a reset transistor 450, an amplification transistor 430, and a selection transistor 440. The electrode 322 and the connection portion 323 described above function as a transfer gate between the semiconductor portion 321 and the semiconductor region 331. As described above, the height of a barrier formed in the connection portion 323 changes by a control signal TX (potential) supplied to the electrode 322, and transfer of the charge from the semiconductor portion 321 to the semiconductor portion 301 is controlled.

A gate of the reset transistor 450 is supplied with a control signal RES. When the reset transistor 450 is brought into an on state in response to the control signal RES, the potential of the semiconductor region 331 functioning as the floating diffusion is reset to a predetermined potential.

The amplification transistor 430 is connected between a predetermined potential and the selection transistor 440. The gate 332 and the semiconductor region 333 illustrated in FIG. 17 correspond to the gate and source-drain of the amplification transistor 430. The amplification transistor 430 constitutes an input portion of a source follower that reads out a signal obtained by photoelectric conversion.

The selection transistor 440 is connected between the amplification transistor 430 and a vertical signal line SIG. A gate electrode of the selection transistor 440 is supplied with a control signal SEL. When the selection transistor 440 is brought into an on state in response to the control signal SEL, the pixel 101 is brought into a selected state, and a signal is output from the amplification transistor 430 to the vertical signal line SIG.

The configurations of the above-described embodiments can be appropriately combined and used. For example, one or more of the charge collection region 317, the pinning layer 320, the semiconductor region 324, and the light shielding portion 325 may be arranged in the pixel 101 illustrated in FIG. 6. For example, the pixel 101 supported in FIGS. 13 and 14 may be applied with a configuration in which the connection portion 323 as illustrated in FIG. 6 is not arranged, or may be applied with a configuration in which the plurality of connection portions 323 as illustrated in FIG. 11 are arranged.

Hereinafter, application examples of the photoelectric conversion apparatus 100 in which the above-described pixels 101 are arranged will be described.

FIG. 19 is a block diagram illustrating a schematic configuration of a photoelectric conversion system. The photoelectric conversion apparatus 100 described in each of the above-described embodiments can be applied to various photoelectric conversion systems. Examples of applicable photoelectric conversion systems include digital still cameras, digital camcorders, surveillance cameras, copiers, faxes, mobile phones, in-vehicle cameras, and observation satellites. A camera module including an optical system such as a lens and an image capturing apparatus is also included in the photoelectric conversion system. FIG. 19 illustrates a block diagram of a digital still camera as an example of them.

A photoelectric conversion system 1000 illustrated in FIG. 19 includes an image capturing apparatus 1004 that is an example of a photoelectric conversion apparatus, a lens 1002 that forms an optical image of a subject on the image capturing apparatus 1004, a aperture 1003 for making the amount of light passing through the lens 1002 variable, and a barrier 1001 for protecting the lens 1002. The lens 1002 and the aperture 1003 are an optical system (optical apparatus) that condenses light on the image capturing apparatus 1004. The image capturing apparatus 1004 is the photoelectric conversion apparatus 100 (image capturing apparatus) of any of the above-described embodiments, and converts an optical image formed by the lens 1002 into an electric signal.

The photoelectric conversion system 1000 includes a signal processing unit 1007 that is an image generation portion that generates an image by processing an output signal output by the image capturing apparatus 1004. The signal processing unit 1007 functions as a processing apparatus that performs an operation of outputting image data by performing various types of correction and compression as necessary. The signal processing unit 1007 may be formed on a semiconductor substrate provide with the image capturing apparatus 1004, or may be formed on a semiconductor substrate different from the image capturing apparatus 1004. The image capturing apparatus 1004 and the signal processing unit 1007 may be formed on the same semiconductor substrate.

The photoelectric conversion system 1000 further includes a memory unit 1010 for temporarily storing image data, and an external interface unit (external I/F unit) 1013 for communicating with an external computer or the like. Furthermore, the photoelectric conversion system 1000 includes a recording medium 1012 such as a semiconductor memory for recording or reading out imaging data, and a recording medium control interface unit (recording medium control I/F unit) 1011 for recording or reading out imaging data on or from the recording medium 1012. The recording medium control I/F unit 1011 and the recording medium 1012 can constitute a part of the storage apparatus. Note that the recording medium 1012 may be built in the photoelectric conversion system 1000 or may be detachable.

Furthermore, the photoelectric conversion system 1000 includes an general control/arithmetic unit 1009 that performs various calculations and controls the entire digital still camera, and a timing generation unit 1008 that outputs various timing signals to the image capturing apparatus 1004 and the signal processing unit 1007. The general control/arithmetic unit 1009 and the timing generation unit 1008 can constitute a part of the control apparatus for controlling the operation of the photoelectric conversion system 1000. Here, the timing signal and the like may be input from the outside, and the photoelectric conversion system 1000 may include at least the image capturing apparatus 1004 and the signal processing unit 1007 that processes the output signal output from the image capturing apparatus 1004.

The image capturing apparatus 1004 outputs an image signal to the signal processing unit 1007. The signal processing unit 1007 performs predetermined signal processing on the image signal output from the image capturing apparatus 1004 and outputs image data. The signal processing unit 1007 generates an image using the image signal. Although not illustrated in FIG. 19, a display apparatus such as a display for displaying a generated image may be arranged in the photoelectric conversion system 1000. As described above, according to the present embodiment, it is possible to achieve the photoelectric conversion system 1000 applied with the photoelectric conversion apparatus 100 (image capturing apparatus) of any of the above-described embodiments.

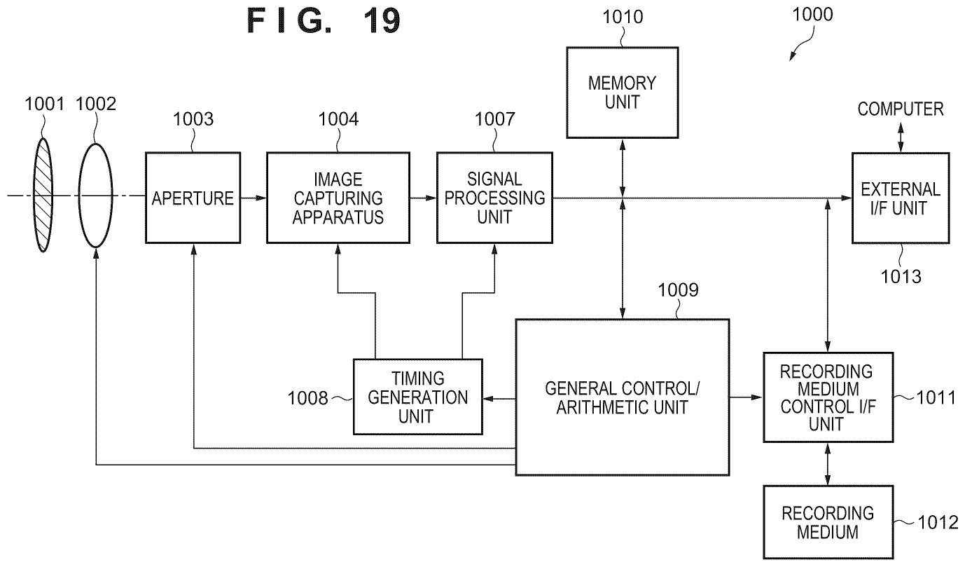

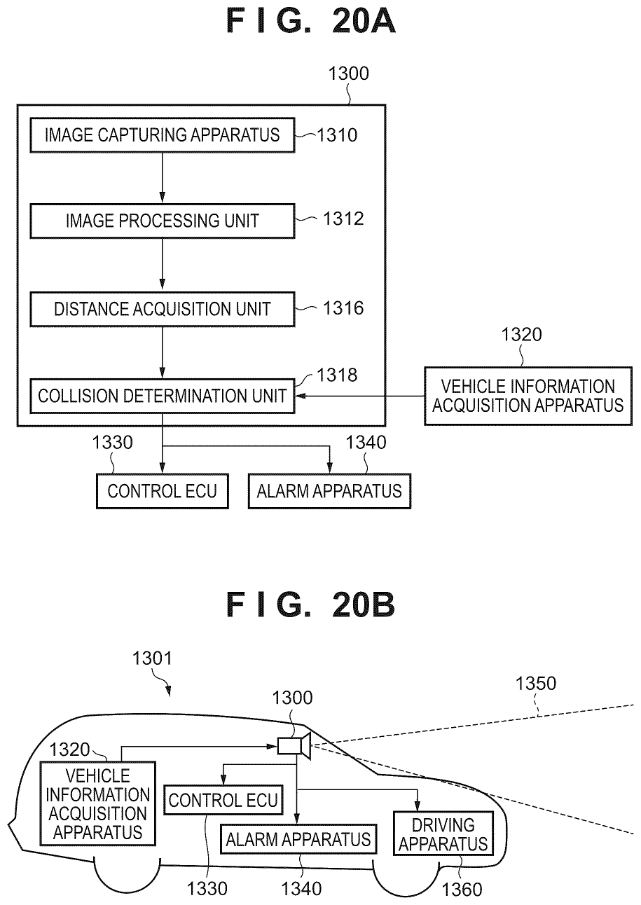

FIGS. 20A and 20B are views illustrating the configurations of a photoelectric conversion system 1300 and a moving body 1301. FIG. 20A illustrates an example of a photoelectric conversion system related to an in-vehicle camera. The photoelectric conversion system 1300 includes an image capturing apparatus 1310. The image capturing apparatus 1310 is the photoelectric conversion apparatus 100 (image capturing apparatus) according to any of the above-described embodiments. The photoelectric conversion system 1300 includes an image processing unit 1312 that performs image processing on a plurality of pieces of image data acquired by the image capturing apparatus 1310. The photoelectric conversion system 1300 includes a distance acquisition unit 1316 that calculates a distance to an object, and a collision determination unit 1318 that determines whether or not there is a possibility of collision based on the calculated distance. Here, the distance acquisition unit 1316 may acquire the distance information to the object using the time of flight (ToF) method, or may acquire distance information using parallax information or the like. That is, the distance information is information regarding parallax, a defocus amount, a distance to an object, and the like. The collision determination unit 1318 may determine the possibility of collision using any of these pieces of distance information. The distance acquisition unit 1316 may be implemented by dedicated hardware or may be implemented by a software module. The distance acquisition unit 1316 may be implemented by a field programmable gate array (FPGA), an application specific integrated circuit (ASIC), or the like, or may be implemented by a combination them.

The photoelectric conversion system 1300 is connected to a vehicle information acquisition apparatus 1320, and can acquire vehicle information such as a vehicle speed, a yaw rate, and a steering angle. The photoelectric conversion system 1300 is connected to a control ECU 1330 that is a control apparatus that outputs a control signal for generating a braking force on the vehicle based on a determination result in the collision determination unit 1318. The photoelectric conversion system 1300 is connected also to an alarm apparatus 1340 that issues an alarm to a driver based on the determination result of the collision determination unit 1318. For example, in a case where the possibility of collision is high as a determination result of the collision determination unit 1318, the control ECU 1330 controls a driving apparatus (mechanical apparatus) 1360 such as applying a brake, returning an accelerator, or suppressing engine output, and performs vehicle control for avoiding collision and reducing damage. The alarm apparatus 1340 gives an alarm to the user by setting off an alarm such as sound, displaying alarm information on a screen of a car navigation system or the like, giving vibration to a seat belt or a steering wheel, or the like.

In the present embodiment, the periphery of a vehicle (moving body 1301), for example, the front or rear, is imaged by the photoelectric conversion system 1300. FIG. 20B illustrates the photoelectric conversion system in a case of imaging the front of the vehicle (imaging range 1350). The vehicle information acquisition apparatus 1320 sends an instruction to the photoelectric conversion system 1300 or the image capturing apparatus 1310. Such a configuration can further improve the accuracy of distance measurement.

In the above, an example of control not to collide with another vehicle has been described, but the photoelectric conversion system 1300 is also applicable to control of performing automatic driving following another vehicle, control of performing automatic driving not to stray from a lane, and the like. Furthermore, the photoelectric conversion system 1300 is not limited to a vehicle such as an automobile, and can be applied to a moving body (moving apparatus) such as a ship, an aircraft, or an industrial robot, for example. The moving body includes one or both of a driving force generation portion that generates a driving force mainly used for movement of the moving body and a rotating body mainly used for movement of the moving body. The driving force generation portion can be an engine, a motor, or the like. The rotating body can be a tire, a wheel, a screw of a ship, a propeller of a flying body, or the like. The photoelectric conversion system 1300 can be applied not only to a moving body but also to equipment that widely uses object recognition, such as intelligent transport systems (ITS).

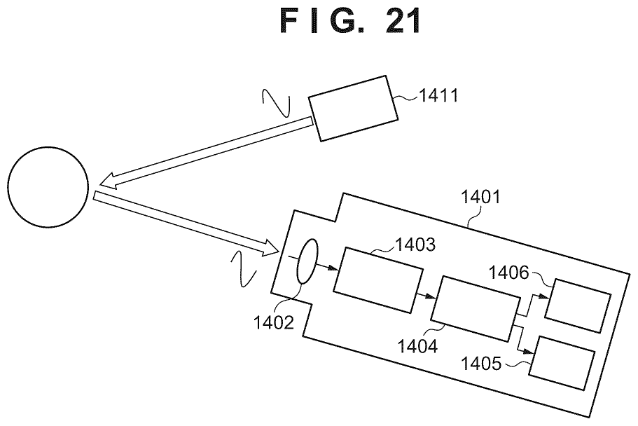

FIG. 21 is a block diagram illustrating a configuration example of a distance image sensor 1401 that is a photoelectric conversion system. As illustrated in FIG. 21, the distance image sensor 1401 includes an optical system 1402, a photoelectric conversion apparatus 1403, an image processing circuit 1404, a monitor 1405, and a memory 1406. Then, the distance image sensor 1401 can acquire a distance image in accordance with the distance to a subject by receiving light (modulated light or pulsed light) projected from a light source apparatus 1411 toward the subject and reflected on the surface of the subject.

The optical system 1402 is configured to include one or a plurality of lenses, guides image light (incident light) from the subject to the photoelectric conversion apparatus 1403, and forms an image on a light receiving surface (sensor portion) of the photoelectric conversion apparatus 1403.

The photoelectric conversion apparatus 1403 is applied with the photoelectric conversion apparatus 100 of each of the above-described embodiments, and a distance signal indicating a distance obtained from a light reception signal output from the photoelectric conversion apparatus 1403 is supplied to the image processing circuit 1404.

The image processing circuit 1404 performs image processing of constructing a distance image based on a distance signal supplied from the photoelectric conversion apparatus 1403. Then, the distance image (image data) obtained by the image processing is supplied to and displayed on the monitor 1405, or supplied to and stored (recorded) in the memory 1406.

In the distance image sensor 1401 configured as described above, by applying the photoelectric conversion apparatus 100 described above, it is possible to acquire, for example, a more accurate distance image along with improvement of the characteristics of the pixels.

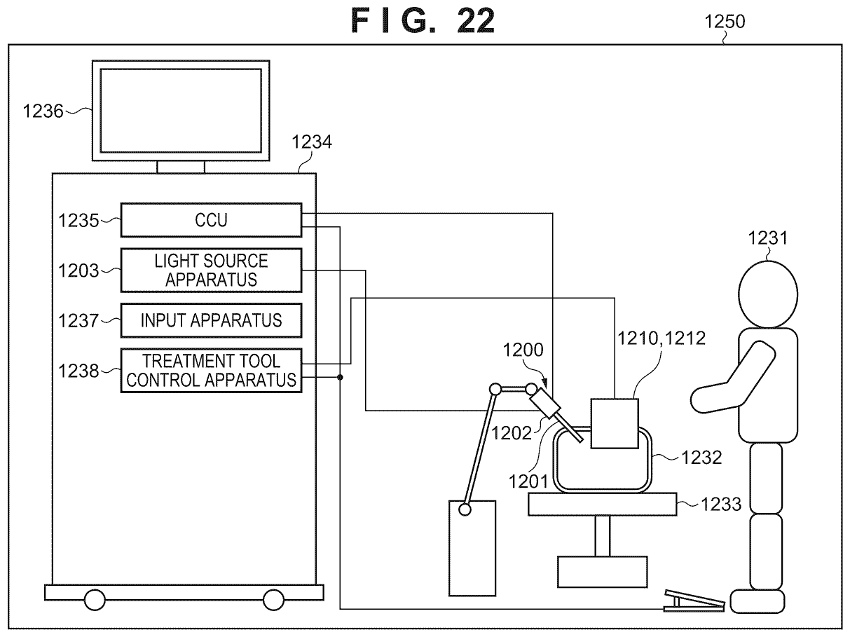

FIG. 22 is a view illustrating an example of a schematic configuration of an endoscopic surgery system 1250 that is a photoelectric conversion system. FIG. 22 illustrates a scene in which an operator (medical doctor) 1231 is performing surgery on a patient 1232 on a patient bed 1233 using the endoscopic surgery system 1250. As illustrated, the endoscopic surgery system 1250 includes an endoscope 1200, a surgical tool 1210, and a cart 1234 mounted with various apparatuses for endoscopic surgery.

The endoscope 1200 includes a lens barrel 1201 in which a region of a predetermined length from the distal end is inserted into the body cavity of the patient 1232, and a camera head 1202 connected to the proximal end of the lens barrel 1201. In the illustrated example, the endoscope 1200 configured as a so-called rigid scope having the rigid lens barrel 1201 is illustrated, but the endoscope 1200 may be configured as a so-called flexible scope having a flexible lens barrel.

The distal end of the lens barrel 1201 is provided with an opening fitted with an objective lens. A light source apparatus 1203 is connected to the endoscope 1200, and light generated by the light source apparatus 1203 is guided to the distal end of the lens barrel by a light guide extending inside the lens barrel 1201, and is emitted toward an observation target in the body cavity of the patient 1232 via the objective lens. Note that the endoscope 1200 may be a forward-viewing endoscope, an oblique-viewing endoscope, or a side-viewing endoscope.

An optical system and a photoelectric conversion apparatus are provided inside the camera head 1202, and reflected light (observation light) from the observation target is condensed on the photoelectric conversion apparatus by the optical system. Observation light is photoelectrically converted by the photoelectric conversion apparatus, and an electric signal corresponding to the observation light, that is, an image signal corresponding to the observation image is generated. As the photoelectric conversion apparatus, the photoelectric conversion apparatus 100 (image capturing apparatus) described in each of the above-described embodiments can be used. The image signal is transmitted to a camera control unit (CCU) 1235 as raw data.

The CCU 1235 includes a central processing portion (CPU) and a graphics processing portion (GPU), and integrally controls operation of the endoscope 1200 and a display apparatus 1236. Furthermore, the CCU 1235 receives an image signal from the camera head 1202, and performs various types of image processing for displaying an image based on the image signal, such as development processing (demosaic processing), on the image signal.

The display apparatus 1236 displays an image based on the image signal subjected to the image processing by the CCU 1235 under the control of the CCU 1235.

The light source apparatus 1203 includes a light source such as a light emitting diode (LED), for example, and supplies irradiation light for imaging a surgical site or the like to the endoscope 1200.

An input apparatus 1237 is an input interface for the endoscopic surgery system 1250. The user can input various types of information and instructions to the endoscopic surgery system 1250 via the input apparatus 1237.

A treatment tool control apparatus 1238 controls driving of an energy treatment tool 1212 for cauterization and incision of tissue, sealing of a blood vessel, or the like.

The light source apparatus 1203 that supplies irradiation light for imaging the surgical site to the endoscope 1200 can include, for example, an LED, a laser light source, or a white light source including a combination thereof. In a case where the white light source includes a combination of RGB laser light sources, since the output intensity and the output timing of each color (each wavelength) can be controlled with high accuracy, the light source apparatus 1203 can perform adjustment of white balance of a captured image. In this case, by irradiating the observation target with laser light from each of the RGB laser light sources in a time division manner and controlling driving of an imaging element of the camera head 1202 in synchronization with the irradiation timing, it is also possible to capture an image corresponding to each of RGB in a time division manner. According to this method, a color image can be obtained without providing the imaging element with a color filter.

The driving of the light source apparatus 1203 may be controlled so as to change, every predetermined time, the intensity of light to be output. By controlling the driving of the imaging element of the camera head 1202 in synchronization with the timing of change of the intensity of the light to acquire images in a time division manner and synthesizing the images, it is possible to generate an image of a high dynamic range without so-called blocked up shadows and blown out highlights.

The light source apparatus 1203 may be configured to be able to supply light in a predetermined wavelength band corresponding to special light observation. In the special light observation, for example, wavelength dependency of light absorption in a body tissue is used. Specifically, a predetermined tissue such as a blood vessel in a mucosal surface layer is imaged with high contrast by emitting light in a narrower band than irradiation light (i.e., white light) at the time of normal observation. Alternatively, in the special light observation, fluorescence observation for obtaining an image using fluorescence generated by irradiation with excitation light may be performed. In the fluorescence observation, it is possible to irradiate a body tissue with excitation light to observe fluorescence from the body tissue, or to locally inject a reagent such as indocyanine green (ICG) into a body tissue and irradiate the body tissue with excitation light corresponding to a fluorescence wavelength of the reagent to obtain a fluorescence image, for example. The light source apparatus 1203 can be configured to be able to supply narrow band light and/or excitation light corresponding to such special light observation.

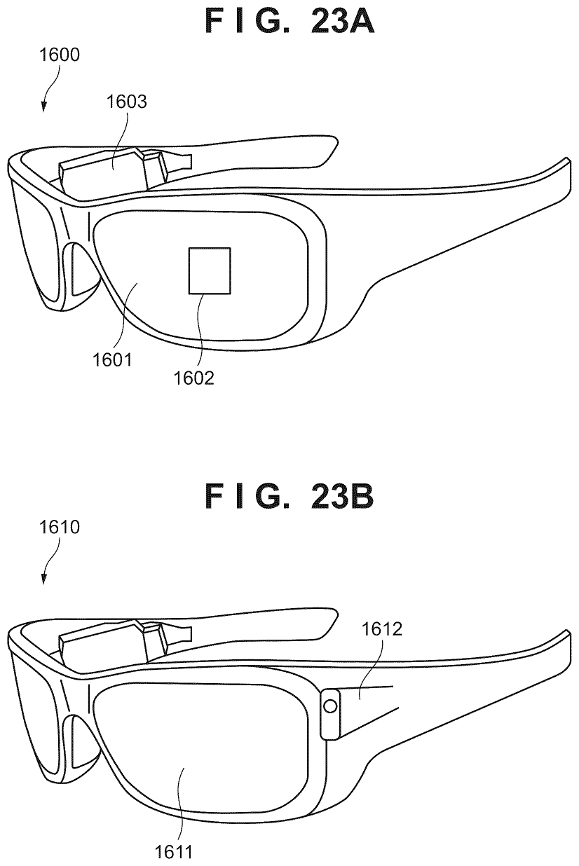

FIGS. 23A and 23B illustrate eyeglasses 1600 (smart glasses) that is a photoelectric conversion system. The eyeglasses 1600 illustrated in FIG. 23A includes a photoelectric conversion apparatus 1602. The photoelectric conversion apparatus 1602 is the photoelectric conversion apparatus 100 (image capturing apparatus) described in each of the above-described embodiments. The back surface side of a lens 1601 may be provided with a display apparatus including a light emitting device such as an OLED or an LED. The number of photoelectric conversion apparatus 1602 may be one or plural. A plurality of types of photoelectric conversion apparatuses may be used in combination. The arrangement position of the photoelectric conversion apparatus 1602 is not limited to that of FIG. 23A.

The eyeglasses 1600 further includes a control apparatus 1603. The control apparatus 1603 functions as a power source that supplies power to the photoelectric conversion apparatus 1602 and the display apparatus. The control apparatus 1603 controls operations of the photoelectric conversion apparatus 1602 and the display apparatus. The lens 1601 is provided with an optical system for condensing light on the photoelectric conversion apparatus 1602.

FIG. 23B illustrates eyeglasses 1610 (smart glasses) according to one application example. The eyeglasses 1610 includes a control apparatus 1612, and the control apparatus 1612 is mounted with a photoelectric conversion apparatus corresponding to the photoelectric conversion apparatus 1602 and a display apparatus. A photoelectric conversion apparatus in the control apparatus 1612 and an optical system for projecting light emitted from the display apparatus are formed on the lens 1611, and an image is projected onto the lens 1611. The control apparatus 1612 functions as a power source that supplies power to the photoelectric conversion apparatus and the display apparatus, and controls operations of the photoelectric conversion apparatus and the display apparatus. The control apparatus may include a line-of sight detection unit that detects the line-of sight of the wearer. Detection of the line-of sight may use infrared light. An infrared light emitting unit emits infrared light to the eye of the user gazing at a display image. A captured image of the eye is acquired by detecting, by the image capturing unit including a light-receiving element, the reflected light of the emitted infrared light from the eye. It is possible to suppress reduction of image quality by providing a reduction unit that reduces incident light from the infrared light emitting unit to the display unit in plan view.

A line-of sight of the user with respect to the display image is detected from a captured image of an eye obtained by imaging infrared light. Any known technique can be applied to line-of sight detection using the captured image of the eye. As an example, a line-of sight detection method can be used, which is based on a Purkinje image formed by reflection of irradiated light at the cornea.

More specifically, a line-of sight detection process based on the pupil corneal reflection method is performed. A line-of sight vector indicating the orientation (rotation angle) of the eye is calculated based on an image of the pupil included in the captured image of the eye and a Purkinje image using the pupil corneal reflection method, whereby the line-of sight of the user is detected.

The display apparatus of the present embodiment may include a photoelectric conversion apparatus having a light-receiving element, and may control a display image of the display apparatus based on line-of sight information of the user from the photoelectric conversion apparatus.

Specifically, the display apparatus determines a first field of view region at which the user gazes and a second field of view region other than the first field of view region based on the line-of sight information. The first field of view region and the second field of view region may be determined by the control apparatus of the display apparatus, or may be received as those determined by an external control apparatus. In the display region of the display apparatus, the display resolution of the first field of view region may be controlled to be higher than the display resolution of the second field of view region. In other words, the resolution of the second field of view region may be set lower than the first field of view region.

The display region may have a first display region and a second display region different from the first display region, and a region having a high priority may be determined from the first display region and the second display region based on the line-of sight information. The first field of view region and the second field of view region may be determined by the control apparatus of the display apparatus, or may be received as those determined by an external control apparatus. The resolution of the higher priority region may be controlled to be higher than the resolution of regions other than the higher priority region. In other words, resolution of the region with a relatively low priority may be reduced.

Here, AI may be used for determining the first field of view region or a region with a higher priority. AI may be a model configured to estimate, from an image of an eye, the angle of the line of sight and the distance to an object beyond the line-of sight, using images of eyes and directions in which the eyes in the images are actually gazing, as supervised data. An AI program may be included in the display apparatus, may be included in the photoelectric conversion apparatus, or may be included in the external device. In a case where an external device includes the AI program, it is transmitted to the display apparatus via communication.

When display control is performed based on visual recognition detection, the present invention can be applied to smart glasses further including a photoelectric conversion apparatus that images the outside. The smart glasses can display the captured external information in real time.

According to the present disclosure, it is possible to provide techniques that are advantageous for noise suppression.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-174631, filed Oct. 6, 2023, which is hereby incorporated by reference herein in its entirety.

What is claimed is:

1. A photoelectric conversion apparatus in which a plurality of pixels are arranged on a substrate made of a first semiconductor material, wherein
each of the plurality of pixels comprises: a first semiconductor portion provided on the substrate; a second semiconductor portion made of a second semiconductor material having a band gap smaller than a band gap of the first semiconductor material; a connection portion in contact with the first semiconductor portion and the second semiconductor portion and including at least one of the first semiconductor material and the second semiconductor material; and an electrode surrounding the connection portion,
wherein in orthogonal projection to a main surface of the substrate, the connection portion is smaller than the second semiconductor portion, and
at least a part of the electrode is arranged between the first semiconductor portion and the second semiconductor portion.

2. The photoelectric conversion apparatus according to claim 1, wherein the electrode does not surround the second semiconductor portion.

3. The photoelectric conversion apparatus according to claim 1, wherein the electrode is not in contact with the connection portion.

4. The photoelectric conversion apparatus according to claim 1, wherein in orthogonal projection to the main surface of the substrate, the connection portion is circular.

5. The photoelectric conversion apparatus according to claim 1, wherein
a plurality of the connection portions are arranged in each of the plurality of pixels, and
the electrode surrounds each of the plurality of connection portions.

6. The photoelectric conversion apparatus according to claim 1, wherein the electrode is not in contact with the first semiconductor portion and the second semiconductor portion.

7. The photoelectric conversion apparatus according to claim 1, wherein in the electrode, an area of an inner side surface extending in a direction intersecting a surface facing the first semiconductor portion is larger than an area of the surface facing the first semiconductor portion.

8. The photoelectric conversion apparatus according to claim 1, wherein the first semiconductor material contains silicon, and the second semiconductor material contains germanium.

9. The photoelectric conversion apparatus according to claim 1, wherein
the plurality of pixels include a first pixel and a second pixel arranged adjacent to each other, and
the electrode of the first pixel and the electrode of the second pixel are integrally formed.

10. The photoelectric conversion apparatus according to claim 1, wherein an avalanche photodiode is arranged in the first semiconductor portion.

11. The photoelectric conversion apparatus according to claim 10, wherein the avalanche photodiode includes an avalanche multiplication region in which a first semiconductor region of a first conductivity type and a second semiconductor region of a second conductivity type arranged between the first semiconductor region and the second semiconductor portion are in contact.

12. The photoelectric conversion apparatus according to claim 11, wherein the first semiconductor portion further includes a third semiconductor region of the first conductivity type arranged between the avalanche multiplication region and the second semiconductor portion, and a fourth semiconductor region having an impurity concentration lower than an impurity concentration of the third semiconductor region arranged between the third semiconductor region and the second semiconductor portion.

13. The photoelectric conversion apparatus according to claim 11, wherein a potential supply electrode for supplying a potential to the second semiconductor region via a fifth semiconductor region of the second conductivity type is arranged.

14. The photoelectric conversion apparatus according to claim 13, wherein
the potential supply electrode includes a side surface and an upper surface in contact with the fifth semiconductor region,
the side surface is covered with an insulator, and
the upper surface is arranged at a position closer to the second semiconductor portion than the first semiconductor region.

15. The photoelectric conversion apparatus according to claim 1, wherein
a light shielding portion is arranged between the plurality of pixels, and
the light shielding portion supplies a potential to the second semiconductor portion.

16. The photoelectric conversion apparatus according to claim 15, wherein the light shielding portion supplies a potential to the second semiconductor portion from a side of a surface of the second semiconductor portion on an opposite side to a surface facing the first semiconductor portion.

17. The photoelectric conversion apparatus according to claim 1, wherein
the second semiconductor portion and the electrode are arranged in an insulator arranged on the substrate, and
the insulator is provided with a wiring pattern for supplying a potential to each of the second semiconductor portion and the electrode.

18. The photoelectric conversion apparatus according to claim 17, wherein the wiring pattern is supplied with power outside a pixel region in which the plurality of pixels are arranged.

19. Equipment comprising:
the photoelectric conversion apparatus according to claim 1; and
a signal processing portion that generates an image using a signal output from the photoelectric conversion apparatus.

20. A moving body including the photoelectric conversion apparatus according to claim 1 comprising:
a control apparatus that controls movement of the moving body using a signal output from the photoelectric conversion apparatus.

21. Equipment including the photoelectric conversion apparatus according to claim 1 further comprising at least any of:
an optical apparatus corresponding to the photoelectric conversion apparatus;
a control apparatus that controls the photoelectric conversion apparatus;
a processing apparatus that processes a signal output from the photoelectric conversion apparatus;
a display apparatus that displays information obtained by the photoelectric conversion apparatus;
a storage apparatus that stores information obtained by the photoelectric conversion apparatus; and
a mechanical apparatus that operates based on information obtained by the photoelectric conversion apparatus.
